(19) United States
(12) Patent Application Publication
(10) Pub. No.: US 2015/0214136 A1
(43) Pub. Date: Jul. 30, 2015

(54) SEMICONDUCTOR DEVICE HAVING LEADFRAME WITH PRESSURE-ABSORBING PAD STRAPS

(71) Applicant: Texas Instruments Incorporated, Dallas, TX (US)

(72) Inventors: Han Meng @Eugene Lee Lee, Johor (MY); Sueann Lim Wei Fen, Melaka (MY)

(73) Assignee: Texas Instruments Incorporated, Dallas, TX (US)

(21) Appl. No.: 14/168,720

(22) Filed: Jan. 30, 2014

(51) Int. Cl. H01L 23/495; H01L 21/56; H01L 23/00; H01L 23/28

(52) U.S. Cl. CPC H01L 23/49503; H01L 23/28; H01L 21/56; H01L 24/83; H01L 24/85; H01L 24/49

(57) ABSTRACT

A leadframe (300) for use in semiconductor devices, comprising an assembly pad (3010 having rectangular sides, the pad extending, on one pad side (301b), into a lead (302) and, on the opposite pad side (301a), into straps (350) oriented normal to the side (301a) and anchored in adjacent tie bars (313), strap surfaces having recesses (501, 502) suitable for interlocking with packaging materials. The leadframe further includes a plurality of leads (303) parallel to and alternating with the straps.

### FIELD OF THE INVENTION

The present invention is related in general to the field of semiconductor devices and processes, and more specifically to the structure of planar leadframes designed to absorb pressure against the assembly pad and to stabilize leadframe planarity throughout the fabrication flow.

### DESCRIPTION OF RELATED ART

Semiconductor power devices and integrated circuit devices which can carry high currents and dissipate significant operational heat include many product families of various designs. In the most popular families, a device includes a semiconductor chip attached to a planar metallic leadframe, wherein the chip is connected by bonding wires to the leads, and chip and wires are encapsulated in a plastic package.

An example of a planar leadframe strip 100 for a plurality of units of a particular product family is illustrated in FIG. 1. In this example, each chip pad 101 of the units continues with practically undiminished width into a broad lead 102, which will continue outside the plastic package after the encapsulation process and can then be formed. Lead 102, in turn, is stabilized by tie bars 112. All other leads 103 are separated from the pad 101 by gaps 104; leads 103 are stabilized by tie bars 113. As shown in FIG. 1, every other unit is connected to the frame by an external tie bar 120. The market trend of these products is towards plastic packages with low height, requiring that the bonding wires are spanned with low arches.

After semiconductor chips have been attached to all pads 101 of the leadframe strip in FIG. 1, each chip is connected to respective leads 103 by bonding wires. After completing the bonding step, a plurality of flat strips 100 are loaded into a cassette to be transported to an encapsulation station (typically a molding press) for the packaging process of encapsulating the bonded chips; thereafter, each leadframe strip with the encapsulated units is subjected to the process steps of trimming, singulating, and forming. It is known that during and after the step of loading into the cassette, each strip 100 needs to retain its flat structure. A cassette typically consists of a vertical array of a number of slot pairs, wherein the slots of each pair are positioned across from and facing each other so that just one strip 100 can be shoved into a coordinated slot pair. After loading, the sides 110 and 111 of a strip are supported by the slots, while the strip 100 remains flat.

### SUMMARY OF THE INVENTION

When applicants analyzed electrical failures at final test of packaged semiconductor devices using the leadframe displayed in FIG. 1, they found in many cases that the root cause of the failures was a contact and thus an electrical short between edge 101a of a tilted leadframe pad 101 (with the attached chip) and a low-arching bonding wire. The tilting of pad 101 was found to originate from a low-angle rotation of pad 101 around an axis formed by tie bars 112. FIG. 2 indicates the tiling of pad 101. The tilting is enabled by the fact that the pad has on one side a robust connection by lead 102 to the frame of the strip, but on the opposite side, edge 101a is facing gaps 104 and is thus not contained by any barrier; edge 101a may perform vibrating and swinging action. Further analysis revealed that the tilting proper can be initiated by bending the strip, when pressure against the strip sides 110 and 111 is exerted. Such pressure may arise, for instance, from forces (designated 220 in FIG. 2), when the strip is slightly angled or mis-oriented while it is loaded into the slots of the transport cassette.

In an effort to find an approach to stabilize pads 101 and avoid a tilting during loading and transportation, a polymeric adhesive tape (for example, about 50 μm thick) has been affixed between pad edge 101a and leads 103. While the tape could be absorbed into the molding compound during the molding operation, it turned out to be too expensive to design and produce the tools for tape cutting and application.

In another effort to strengthen the stability of pads 101, the width of the external tie bars 120 was increased (for example, from about 400 to 500 μm) to make the tie bars more robust against pressure along their long axis in order to keep the pad from tilting. It turned out that any necessary increase of width results in insufficient space for the tie bar insert in the mold chase and thus increased the risk of mold chase cracks to an unacceptable level.

Applicants solved the problem of suppressing pad tilting and thus avoiding electrical shorts with the bonding wires, when they discovered a low-cost method of redesigning the leadframe so that the robust connection of one pad side to the frame (by lead 102) is balanced on the opposite pad side by additional straps anchored in tie bars of the leadframe. At the conclusion of the assembly and packaging cycle, these tie bars will be removed by the trimming and forming process steps. The straps fit geometrically into spaces freed up from the existing layout of the leads, have a length designed to accommodate elongation based upon inherent material characteristics, and have surfaces with recesses suitable for interlocking with packaging materials.

### BRIEF DESCRIPTION OF THE DRAWINGS

FIG. 1 shows a perspective view of a leadframe strip according to prior art, the strip having a plurality of device sites.

FIG. 2 depicts a perspective view of a discrete device site of a leadframe strip, with a semiconductor chip assembled on the pad and wire bonded; the arrows indicate the direction of forces applied to the strip, causing the tilting of the pad.

FIG. 3 illustrates a perspective view of a leadframe strip according to the invention, the pad being anchored by straps to a tie bar.

FIG. 4 shows a close-up view of a strap, exhibiting surface recesses suitable for interlocking with packaging materials.

FIG. 5 depicts a perspective view of a discrete device site of a leadframe strip according to the invention, with a semiconductor chip assembled on the pad and wire bonded; the arrows indicate the direction of forces applied to the strip free from causing the tilting of the pad.

FIG. 6 shows a perspective view of a leadframe strip according to the invention after packaging the assembled chips.

FIG. 7 illustrates a perspective view of a packaged and trimmed devices with formed leads, the package surface exposing the ends of the leadframe pad straps.

### DETAILED DESCRIPTION OF THE PREFERRED EMBODIMENTS

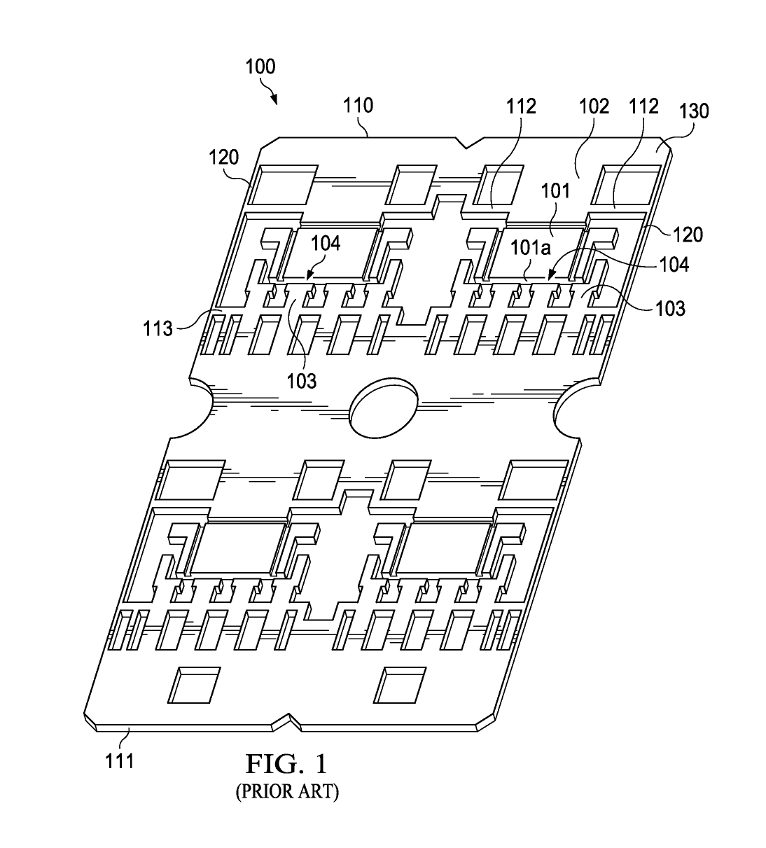

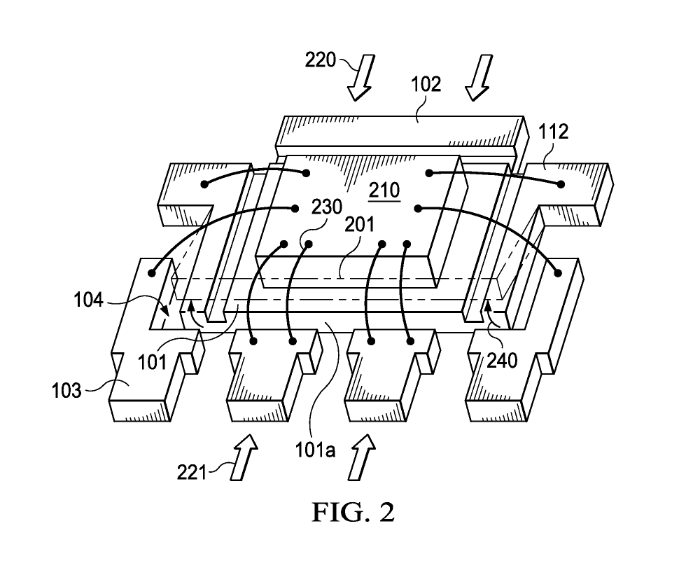

Using conventional leadframe strips as shown in FIG. 1, semiconductor chips 210 were attached to the leadframe pads 101 of the individual sites, subsequently wire bonded to the leads and encapsulated in a packaging compound. A significant portion of the finished devices failed electrically in final testing. Failure analysis showed that in many cases the root cause of the failures was a contact and resulting electrical short between edge 101a of a tilted leadframe pad 101 (with attached chip 210) and a low-arching bonding wire 230 (see FIG. 2). The tilting of pad 101 was found to originate from a low-angle rotation of pad with tie bars 112 acting as an axis. FIG. 2 indicates the new position 201 of pad 101 by dashed outlines, and the movement of the tilting by arrows 240.

The origin of the tilting was found in the reaction of the peculiar structure of the leadframe under the influence of outside forces. As FIGS. 1 and 2 show, a pad 101 has on one side a robust connection by lead 102 to the frame 130 of the strip, but on the opposite side, edge 101a of the pad is facing gaps 104. Pad edge 101a is thus not contained by any barrier and may, consequently, perform limited movement and even vibrating and swinging motion under the influence of an outside force. An example of such movement the tilting of pad 101 into position 201 by outside force 220, which is not balanced by counter-force 221.

Further analysis revealed that a force 220 can be initiated by bending the strip, which puts pressure against the strip sides 110 and 111. Such bending and pressure may, for instance, be caused, when the strip is slightly angled or mis-oriented while it is loaded into the slots of the transport cassette.

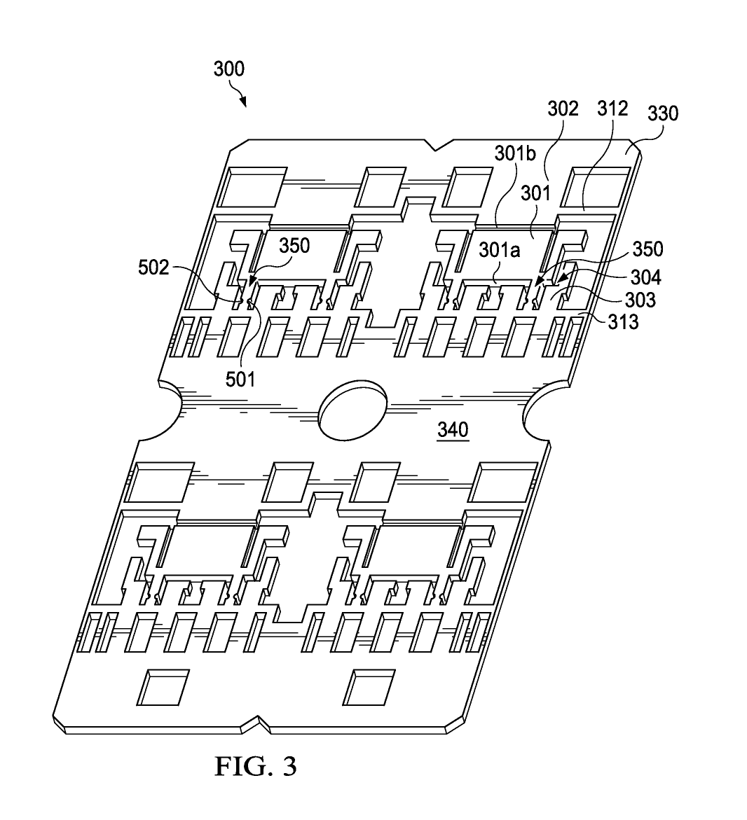

An exemplary embodiment of the invention is based on a leadframe strip stamped or etched from a flat sheet of metal selected from a group including copper, copper alloys, aluminum, iron-nickel alloys, and Kovar™. When the metal sheet is made of copper, the preferred thickness of the sheet is between 100 and 300 μm. For some applications, the sheet may be thicker or thinner. An exemplary embodiment of the invention to suppress the pad tilting even when an outside force initiates some pressure against the outer strip sides is illustrated in FIGS. 3, 4 and 5. FIG. 3 shows as an exemplary embodiment a planar leadframe strip 300 for a plurality of units belonging to a high power, low pin count product family. In this example, each chip assembly pad 301 of the units is rectangular; one side 301b continues with practically undiminished width into a broad lead 302, which, in turn, is tied to outer frame 330. As is illustrated in FIG. 7, lead 302 is continuing outside the plastic package of the device after the encapsulation process, and can be formed by a forming process. Referring to FIG. 3, lead 302 is stabilized by tie bars 312. The pad side opposite to side 301b is designated 301a. Pad side 301a is facing other leads 303, which are separated from the pad side 301a by gaps 304. Leads 303 are stabilized by tie bars 313, but continue to frame 340.

The exemplary embodiment of FIG. 3 further shows that each pad 301 extends, from pad side 301a, into a plurality of straps 350. Straps 350 are oriented normal to side 301. Furthermore, straps 350 are anchored in adjacent tie bars 313, similar to leads 303, but in contrast to leads 303, straps 350 do not continue to frame 340. This means, when tie bars 313 are trimmed after the encapsulation process, the end of straps 350 will be visible at the surface of the encapsulation.

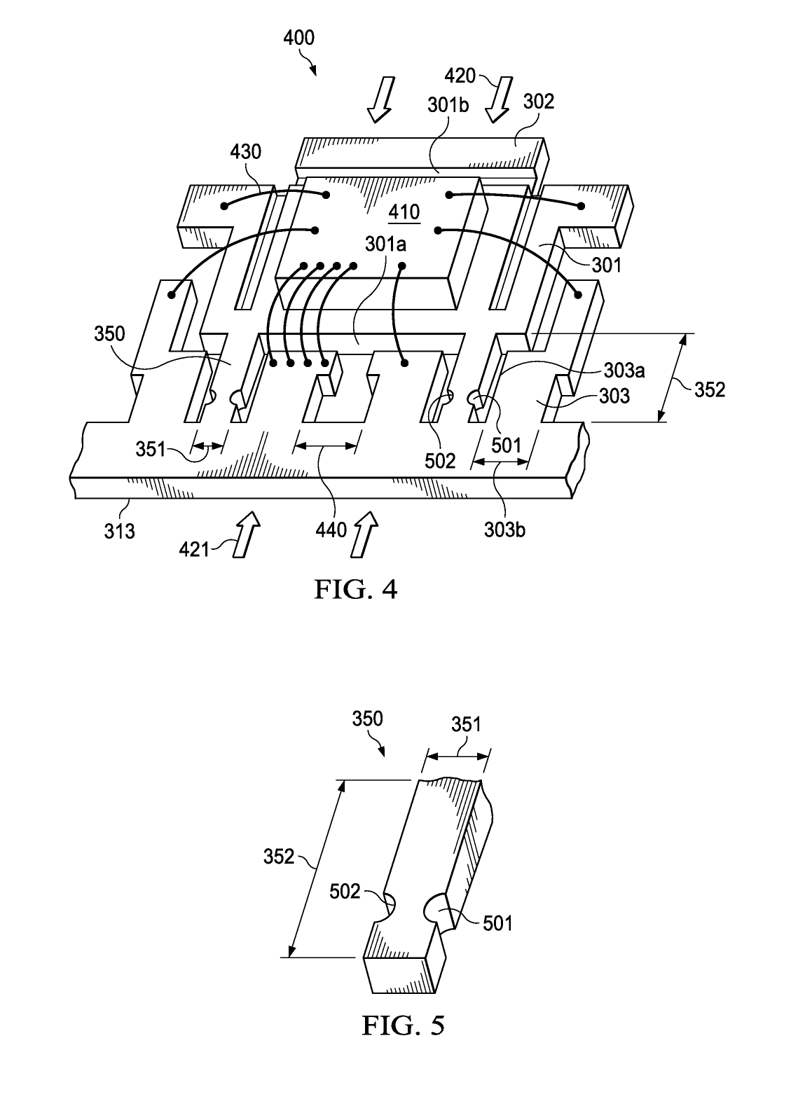

FIG. 4 shows an enlarged view of a discrete leadframe site 400 of exemplary strip 300, after a semiconductor chip 410 has been attached to pad 301 and bonded by wires 430 to respective leads 303. For the leadframe site of the example of FIG. 4, leads 303 have a width 303b of about 750 μm. The separation 440 between adjacent leads is about 850 μm. FIG. 4 includes two straps 350 as connections from pad side 301a to tie bar 313; the strap length 352 may for instance be about 1.25 mm. The width 351 of a tie bar is about 250 μm. In order to provide this space for the tie bars within the constraint of the lead separations 440, special attention had to be given to the end portions 303a of adjacent leads. It is at these end portions that the stitch bonds of wires 430 need to have enough area to be attached according to wire bonding technology capability. FIG. 4 depicts a possible array of four potential stitch bonds adjacent to each other on a single lead end; for a wire diameter of 40 μm, five stitches may be possible. As FIG. 4 shows, by keeping those outlines of leads 303, which face straps 350, as straight contours, clearances of 300 pm on each side of a strap can be maintained.

When an external force 420 acts on the leadframe of FIG. 4, while straps 350 are still affixed to tie bar 313, force 420 it cannot cause movement or tilting of pad 301, because the pad is firmly stabilized by the straps, indicated by counter-force 421. The geometry of length and width of straps 350 is designed to accommodate elongation based upon inherent material characteristics, any elongation is in a direction substantially along the length of straps 350.

While for some devices a single strap may suffice to prevent tilting of the pad, other devices, such as illustrated in the example of FIGS. 3 and 4, have an additional requirement for stable planarity of the pad. Those devices require two or more straps along a side of the pad.

FIG. 5 illustrates another feature of straps 350. In order to interlock straps 350 with the material used for packaging the assembled device by the encapsulation step and to support controlled co-planarity of the assembly pad, straps 350 preferably have recesses in their surfaces. The reduced width of 351, caused by the curvatures 501 and 502, contributes to avoiding mold cracking during the trim-and-form process steps; mold cracking is typically induced by solid metal parts with excessive width. The recesses may have various shapes, such as curved geometry, or pointed indents and grooves. As an example FIG. 5 shows the round outline of recesses 501 and 502 comprising portions of a circle of 350 μm diameter. The surface recesses may be one-sided, or symmetrical as in FIG. 5, and are preferably near the end of the strap at the package surface after the trimming step.

Another embodiment of the invention is a method for fabricating a high power, low pin count semiconductor device. Certain steps of the method are depicted in FIGS. 3 through 7. In FIG. 3, the method starts by providing a leadframe strip 300, which has a plurality of device sites. Each site is patterned into an assembly pad 301 with rectangular sides. Pad 301 extends, on pad side 301b, into a lead 302 and, on the opposite pad side 301a, into a plurality of straps 350, which are oriented normal to side 301a. Straps 350 are anchored in adjacent tie bars 313. Furthermore, a plurality of strap surfaces has recesses 501, 502 for interlocking with package materials. The leadframe of FIG. 3 also has a plurality of leads 303, which are parallel to and alternating with the straps.

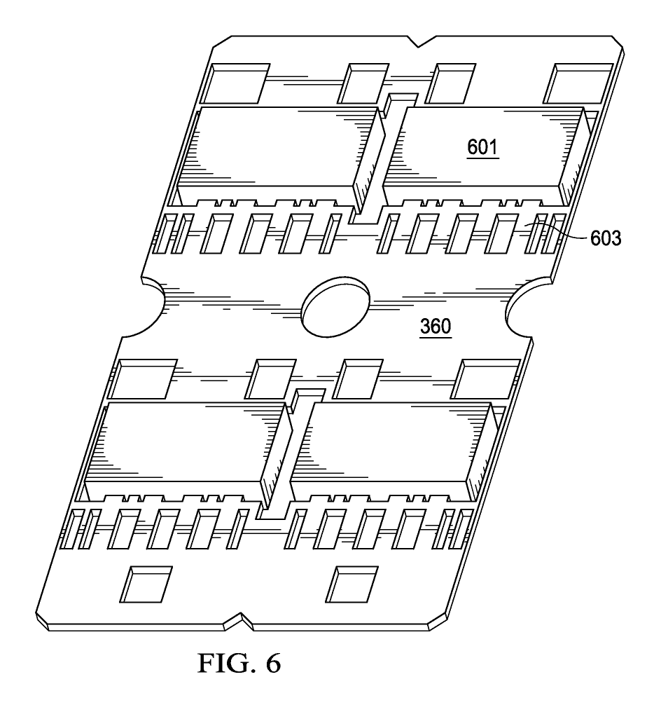

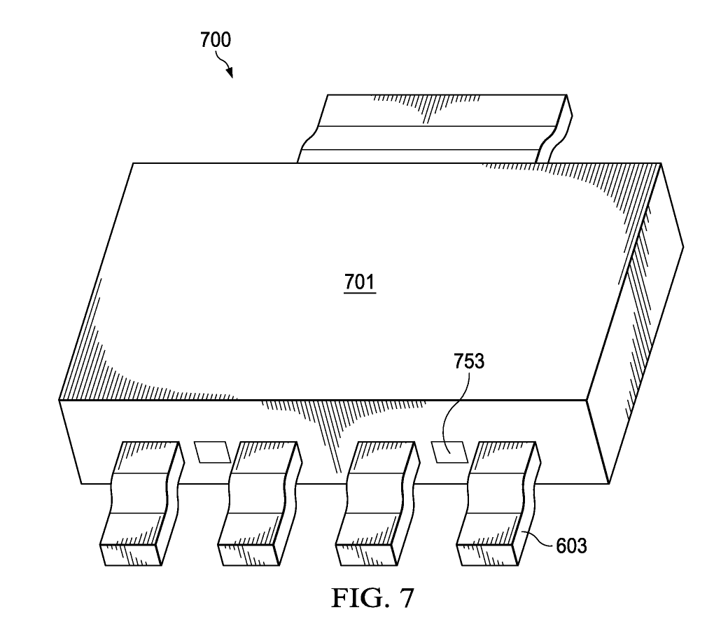

In the next process steps (see FIG. 4), semiconductor chips 410 are attached onto the pads 301. Each chip is then connected to respective leads 303 using bonding wires 430. Thereafter, the assembled chip of each site, together with the wires and the straps, are encapsulated in a packaging material, thus forming a plurality of packaged devices 601 (see FIG. 6). In a preferred process, the encapsulation is molding technique using an epoxy-based polymeric compound. During the encapsulation process, the packaging material interlocks with the surface recesses 501, 502 of the straps 350. Due to the interlocking of metallic straps and a polymeric compound, cracking of the hardened (polymerized) compound during the mechanically stressful trim-and-form processes can be avoided. FIG. 6 shows that portions of the leads near the tie bars 312 and 313, as well as portions 603 remote from pads 301 remain un-encapsulated.

After the encapsulation step, it is advantageous for many devices to add a plating step for the un-encapsulated portions 360 of the leadframe (see FIG. 6) in order to deposit at least one layer of a solderable metal onto the base metal of the leadframe.

In the next process step, shown in FIG. 7, the leadframe strip is trimmed by severing the straps 350 at the surface of the packages and singulating the strip into discrete packages 700. As a result of this step, the package surface 701 exposes the ends 753 of the straps 350. The method concludes by shaping the un-encapsulated portions 603 of the leads 303 in a form commensurate with the anticipated board assembly method; the lead portions 603 of the exemplary device of FIG. 7 exhibit so-called gull wing leads.

The concept of adding straps to leadframe assembly pads for mechanically stabilizing the pads and concurrently endowing the straps with features for anchoring the straps into the encapsulation material, can be applied to many families of semiconductor devices, such as low and high pin count and high and low power devices. The protections make the devices more robust during unavoidable handling in assembly processes, and more robust during some of the packaging processes proper.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies not only to active semiconductor devices, but also to combinations of active and passive components assembled on a leadframe pad.

As another example, the invention applies to leadframe pads, where the pad extends on one side into more than one lead. As yet another example, the invention applies to pads which are offset from the plane of the leadframe.

It is therefore intended that the appended claims encompass any such modifications or embodiments.

We claim:

1. A leadframe comprising:
an assembly pad having rectangular sides, the pad extending, on one pad side, into a lead and, on the opposite pad side, into straps oriented normal to the side and anchored in adjacent tie bars, strap surfaces having recesses suitable for interlocking with packaging materials; and
a plurality of leads parallel to and alternating with the straps.

2. The leadframe of claim 1 wherein the straps are in the plane of the pad.

3. The leadframe of claim 2 wherein the straps have a geometry with a length designed to accommodate elongation based upon inherent material characteristics and in a direction substantially along the length.

4. The leadframe of claim 3 wherein the straps are trimmed by removing the tie bars.

5. A semiconductor device comprising:
a leadframe having an assembly pad with rectangular sides, the pad extending, on one pad side, into a lead and, on the opposite pad side, into straps oriented normal to the side, strap surfaces having recesses suitable for interlocking with packaging materials; the leadframe further having leads parallel to and alternating with the straps;
a semiconductor chip attached to the pad and wire bonded to the leads; and
a package encapsulating the chip, wires, and straps, a package surface exposing the ends of the straps.

6. A method for fabricating a semiconductor device comprising the steps of:
providing a leadframe strip having a plurality of device sites, each site patterned into an assembly pad with rectangular sides, the pad extending, on one pad side, into a lead and, on the opposite pad side, into straps oriented normal to the side and anchored in adjacent tie bars, strap surfaces having recesses for interlocking with package materials; the leadframe further having leads parallel to and alternating with the straps;
attaching semiconductor chips onto the pads;
connecting each chip to respective leads using bonding wires;
forming a plurality of packages by encapsulating the chip, wires and straps of each site in a packaging material, thereby interlocking the material with the surface recesses of the straps, leaving portions of the leads un-encapsulated;
trimming the leadframe strip by severing the straps at the surface of the packages and singulating the strip into discrete packages; and
forming the un-encapsulated portions of the leads.

7. The method of claim 6 further including, before the step of trimming, the step of plating the un-encapsulated portions of the leadframe with at least one solderable metal layer.
